(19) United States
(12) Patent Application Publication
(10) Pub. No.: US 2016/0285453 A1
(43) Pub. Date: Sep. 29, 2016

(54) DRIVER USING PULL-UP NMOS TRANSISTOR

(71) Applicant: QUALCOMM Incorporated, San Diego, CA (US)

(72) Inventors: Stephen Clifford Thilenius, San Diego, CA (US); Patrick Isakanian, El Dorado Hills, CA (US); Alvin Leng Sun Loke, San Diego, CA (US); Thomas Clark Bryan, Carlsbad, CA (US); LuVerne Ray Peterson, San Diego, CA (US)

(21) Appl. No.: 14/957,188

(22) Filed: Dec. 2, 2015

Related U.S. Application Data
(60) Provisional application No. 62/233,135, filed on Sep. 25, 2015.
(60) Provisional application No. 62/138,312, filed on Mar. 25, 2015.

(51) Int. Cl. H03K 19/0175; H03K 5/14

(52) U.S. Cl. CPC H03K 19/017518; H03K 5/14

(57) ABSTRACT

In one embodiment, a system comprises a pre-driver circuit and a driver. The pre-driver circuit is powered by a first supply voltage, and configured to output a pre-drive signal. The driver comprises a pull-up NMOS transistor having a drain coupled to a second supply voltage, and a source coupled to an output of the driver, wherein the second supply voltage is lower than the first supply voltage by at least a threshold voltage of the pull-up NMOS transistor. The driver also comprises a drive circuit coupled to a gate of the pull-up NMOS transistor, wherein the drive circuit is configured to receive the pre-drive signal and to drive the gate of the pull-up NMOS transistor with a voltage approximately equal to the first supply voltage to drive the output of the driver to a high state depending on a logic state of the pre-drive signal.

### RELATED APPLICATION

This application claims priority under 35 U.S.C. §119(e) to U.S. Provisional Application No. 62/138,312 filed on Mar. 25, 2015, and to U.S. Provisional Application No. 62/233,135 filed on Sep. 25, 2015, the entire specifications of which are incorporated herein by reference.

### BACKGROUND

1. Field

Aspects of the present disclosure relate generally to drivers, and more particularly, to a low swing, low power driver using a pull-up NMOS transistor.

2. Background

A driver may be used to transmit a signal from one device to another device across a channel (e.g., a transmission line). For example, a driver may be used in a memory I/O interface to transmit a data signal and/or a clock signal from a memory controller to an external memory device (e.g., DDR SDRAM), or vice versa.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A first aspect relates to a system. The system comprises a pre-driver circuit and a driver. The pre-driver circuit is powered by a first supply voltage, and configured to output a pre-drive signal. The driver comprises a pull-up NMOS transistor having a drain coupled to a second supply voltage, and a source coupled to an output of the driver, wherein the second supply voltage is lower than the first supply voltage by at least a threshold voltage of the pull-up NMOS transistor. The driver also comprises a drive circuit coupled to a gate of the pull-up NMOS transistor, wherein the drive circuit is configured to receive the pre-drive signal and to drive the gate of the pull-up NMOS transistor with a voltage approximately equal to the first supply voltage to drive the output of the driver to a high state depending on a logic state of the pre-drive signal.

A second aspect relates to a method for driving a driver, the driver comprising a pull-up NMOS transistor having a drain coupled to a first supply voltage and a source coupled to an output of the driver. The method comprises receiving a pre-drive signal from a pre-driver circuit powered by a second supply voltage, wherein the second supply voltage is higher than the first supply voltage by at least a threshold voltage of the pull-up NMOS transistor. The method also comprises driving a gate of the pull-up NMOS transistor with a voltage approximately equal to the second supply voltage to drive the output of the driver to a high state depending on a logic state of the received pre-drive signal.

A third aspects relates to an apparatus for driving a driver, the driver comprising a pull-up NMOS transistor having a drain coupled to a first supply voltage and a source coupled to an output of the driver. The apparatus comprises means for receiving a pre-drive signal from a pre-driver circuit powered by a second supply voltage, wherein the second supply voltage is higher than the first supply voltage by at least a threshold voltage of the pull-up NMOS transistor. The apparatus also comprises means for driving a gate of the pull-up NMOS transistor with a voltage approximately equal to the second supply voltage to drive the output of the driver to a high state depending on a logic state of the received pre-drive signal.

### BRIEF DESCRIPTION OF THE DRAWINGS

FIG. 1 shows an example of a driver with a pull-up NMOS transistor.

FIG. 2A shows a driver with a pull-up NMOS transistor according to an embodiment of the present disclosure.

FIG. 2B shows an example of the driver in FIG. 2A in which a supply voltage is reduced by a voltage-reduction circuit to generate a low supply voltage according to an embodiment of the present disclosure.

FIG. 2C shows an example of the driver in FIG. 2A in which two supply voltages are provided to the driver from an external power source according to an embodiment of the present disclosure.

FIG. 3 shows an exemplary implementation of an inverter according to an embodiment of the present disclosure.

FIG. 4 shows an exemplary implementation of a delay circuit according to an embodiment of the present disclosure.

FIG. 5 shows a driver with a pull-up NMOS transistor according to another embodiment of the present disclosure.

FIG. 6 shows an exemplary communication system in which embodiments of the present disclosure may be used.

FIG. 7 shows an exemplary memory interface in which embodiments of the present disclosure may be used.

FIG. 8 is a flowchart illustrating a method for driving a driver according to an embodiment of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A driver may be used to transmit a signal from one device to another device across a channel (e.g., a transmission line). For example, a driver may be used in a memory interface to transmit a data signal and/or a clock signal from a memory controller to an external memory device (e.g., DDR SDRAM), or vice versa. Lower power at an I/O interface may be achieved by lowering the voltage swing at the driver output, which may be done by lowering the power supply voltage supplied to the driver.

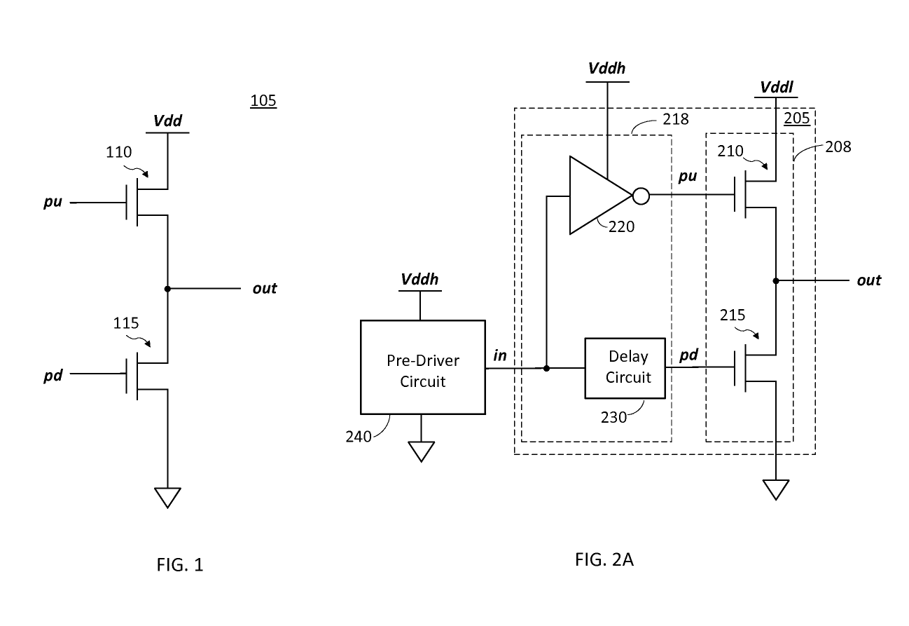

FIG. 1 shows an example of a driver 105 comprising a pull-up N-type metal-oxide-semiconductor (NMOS) transistor 110 and a pull-down NMOS transistor 115. The driver 105 may be used, for example, in an I/O interface (e.g., memory I/O interface) to transmit a data signal and/or a clock signal on a channel (e.g., transmission line) coupled to the output (denoted “out”) of the driver 105.

The pull-NMOS transistor 110 has a drain coupled to a power supply voltage Vdd, and a source coupled to the output of the driver 105. The pull-down NMOS transistor 115 has a drain coupled to the output of the driver 105, and a source coupled to ground. The gate of the pull-up NMOS transistor 110 is driven by a pull-up signal (denoted “pu”) and the gate of the pull-down NMOS transistor 115 is driven by a pull-down signal (denoted “pd”). The pull-up signal and the pull-down signal are complementary signals (i.e., when one of the signals is logic one (high state), the other signal is logic zero (low state)). The pull-up signal and the pull-down signal may each have a voltage swing approximately equal to Vdd.

In operation, the logic states of the pull-up signal and pull-down signal may switch according to the data signal and/or clock signal being transmitted. For instance, when the pull-up signal switches to logic zero (low state) and the pull-down signal switches to logic one (high state), the pull-up NMOS transistor 110 turns off and the pull-down NMOS transistor 115 turns on. As a result, the pull-down NMOS transistor 115 pulls the output of the driver 105 low (e.g., to approximately ground). In this case, the driver 105 transmits a zero bit.

When the pull-up signal switches to logic one (high state) and the pull-down signal switches to logic zero (low state), the pull-up NMOS transistor 110 turns on and the pull-down NMOS transistor 115 turns off. As a result, the pull-up NMOS transistor 110 pulls up the output of the driver 105, in which case, the driver 105 transmits a one bit. The pull-up NMOS transistor 110 might not pull up the output of the driver 105 all the way to the supply voltage Vdd. This is because the gate-to-source voltage of the pull-up NMOS transistor 110 falls below the threshold voltage (denoted “Vt”) of the pull-up NMOS transistor 110 when the output voltage reaches approximately Vdd−Vt. At this point, the impedance looking into the source of the pull-up NMOS transistor 110 may rise very sharply. The rise in impedance degrades the output signal due to mismatch of impedance with the characteristic impedance of the channel.

In addition, when the output voltage reaches approximately Vdd−Vt, the pull-up NMOS transistor 110 may enter the subthreshold region, in which the pull-up NMOS transistor 110 supplies a small amount of leakage current to the channel. This causes the output voltage of the driver 105 to slowly rise (drift higher) over time when the driver 105 transmits a sequence of consecutive one bits. The more consecutive one bits that are transmitted (i.e., the longer the output of the driver 105 stays in the high state), the higher the output voltage becomes as it asymptotically approaches Vdd. As a result, when the output of the driver 105 switches (toggles) from high state to low state to transmit a zero bit, the high-state voltage at the start of the switch may vary depending on the number of consecutive one bits preceding the zero bit. The variation in the high-state voltage causes variation in the time it takes for the voltage at the receiver to cross a reference voltage used at the receiver for deciding whether a bit is a one or a zero and constitutes intersymbol interference (ISI). This variation leads to uncertainty in the timing of the zero bit at the receiver, resulting in deterministic jitter.

Embodiments of the present disclosure overcome the above-mentioned drawbacks by using separate supply voltages for the pull-up NMOS transistor and the pull-up signal. For example, the supply voltage (denoted “Vddh”) used for the pull-up signal may be greater than the supply voltage (denoted “Vddl”) used for the pull-up NMOS transistor by at least the threshold voltage Vt of the pull-up NMOS transistor. Thus, when the pull-up signal is high (logic one), the pull-up signal fully turns on the pull-up NMOS transistor, even as the output voltage of the driver approaches Vddl. As a result, the pull-up NMOS transistor stays in the linear region with a low controllable impedance to preserve signal integrity. In addition, since the pull-up NMOS transistor stays fully turned on, the output voltage of the driver is quickly pulled up to approximately Vddl. As a result, the high-state output voltage of the driver exhibits less variation (less dependent on the number of consecutive one bits), thereby significantly reducing jitter and ISI. Jitter reduction may be essential in communicating at higher data rates.

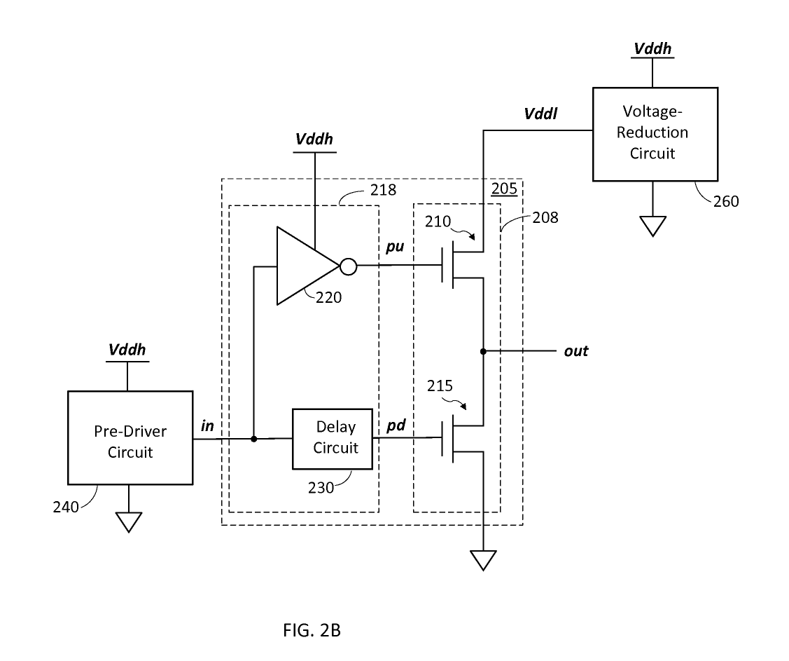

FIG. 2A shows a driver 205 according to an embodiment of the present disclosure. The driver 205 comprises an output stage 208 and a drive circuit 218. The output stage comprises a pull-up NMOS transistor 210, and a pull-down NMOS transistor 215, and the drive circuit 218 comprises an inverter 220, and a delay circuit 230. The driver 205 may be used, for example, in an I/O interface (e.g., memory interface) to transmit a data signal and/or a clock signal on a channel (e.g., transmission line) coupled to the output (denoted “out”) of the driver 205.

The pull-NMOS transistor 210 has a drain coupled to power supply voltage Vddl, and a source coupled to the output of the driver 205. The pull-down NMOS transistor 215 has a drain coupled to the output of the driver 205, and a source coupled to ground. The drive circuit 218 is configured to drive the gate of the pull-up NMOS transistor 210 with a pull-up signal (denoted “pu”) and drive the gate of the pull-down NMOS transistor 215 with a pull-down signal (denoted “pd”), as discussed further below.

The pull-down signal may be provided to the input (denoted “in”) of the drive circuit 218 by a pre-driver circuit 240. The pre-driver circuit 240 may be powered by supply voltage Vddh, which may be greater than supply voltage Vddl by at least the threshold voltage Vt of the pull-up NMOS transistor (i.e., Vddh≧Vddl+Vt). In certain aspects, the supply voltage Vddl may be a core voltage used to power circuits (e.g., processing cores, memory controller, etc.) on the chip on which the driver 205 and pre-driver circuit 240 are implemented. Thus, in these aspects, the supply voltage Vddl used to power the output stage 208 is much lower than the core voltage of the chip, as discussed further below.

In this example, the pull-down signal may have a voltage swing of approximately Vddh. The delay circuit 230 coupled between the input of the drive circuit 218 and the gate of the pull-down signal NMOS transistor 215 is used to delay the pull-down signal by a delay that approximately matches the delay of the inverter 220, as discussed further below.

The inverter 220 is coupled between the input of the drive circuit 218 and the gate of the pull-up NMOS transistor 210. The inverter 220 inverts the pull-down signal to generate the pull-up signal. As a result, the pull-up signal and the pull-down signal are complementary signals. The inverter 220 may be powered by supply voltage Vddh so that the inverter output (and hence the pull-up signal) has a voltage swing of approximately Vddh.

In operation, the drive circuit 218 may switch the logic states of the pull-up and pull-down signals according to the logic state of the output signal of the pre-driver circuit 240, in which the output signal may comprise a data signal and/or clock signal to be transmitted. When the pull-up signal switches to logic zero (low state) and the pull-down signal switches to logic one (high state), the pull-up NMOS transistor 210 turns off and the pull-down NMOS transistor 215 turns on. As a result, the pull-down NMOS transistor 215 pulls the output of the driver 205 low (e.g., to approximately ground). In this case, the driver 105 transmits a zero bit.

When the pull-up signal switches to logic one (high state) and the pull-down signal switches to logic zero (low state), the pull-up NMOS transistor 210 turns on and the pull-down NMOS transistor 215 turns off. As a result, the pull-up NMOS transistor 210 pulls up the output of the driver 205, in which case, the driver 105 transmits a one bit. Because the pull-up signal is approximately equal to supply voltage Vddh in the high state, the pull-up signal fully turns on the pull-up NMOS transistor 210, even as the output voltage of the driver 205 approaches supply voltage Vddl. As a result, the pull-up NMOS transistor 210 stays in the linear region with a low controllable impedance. In addition, since the pull-up NMOS transistor 210 stays fully turned on, the output voltage of the driver 205 is quickly pulled up to approximately Vddl. As a result, the output of the driver 205 has approximately a rail-to-rail voltage swing of Vddl. Thus, the output swing of the driver 205 may be controlled by supply voltage Vddl.

In one example, supply voltage Vddh may be approximately equal to 0.8 volts and supply voltage Vddl may be approximately equal to 0.35 volts. However, it is to be appreciated that the present disclosure is not limited to this example and that supply voltages Vddh and Vddl may have other values.

As discussed above, in certain aspects, the supply voltage Vddh used to power the drive circuit 218 and the pre-driver circuit 240 is a core voltage of the corresponding chip. The core voltage is also used to other power circuits on the chip (processing cores, memory controller, etc.). Thus, in these aspects, the supply voltage Vddl coupled to the drain of the pull-up NMOS transistor 210 is much lower than the core voltage (i.e., lower than the core voltage by at least Vt of the pull-up NMOS transistor 210). The low supply voltage Vddl may be provided by reducing the core voltage to Vddl (e.g., using a voltage divider or other circuit that reduces voltage). In this regard, FIG. 2B shows an example of a voltage-reduction circuit 260 (e.g., a voltage divider) coupled to supply voltage Vddh. In this example, the voltage-reduction circuit 260 reduces supply voltage Vddh (e.g., by at least Vt of the pull NMOS transistor 210) to generate the low supply voltage Vddl.

In another example, the low supply voltage Vddl and core voltage may be provided to the chip from an external power source (e.g., power management integrated circuit (PMIC)). In this regard, FIG. 2C shows an example in which supply voltage Vddh and supply voltage Vddl are separately provided by a PMIC 270 that is external to the chip on which the pre-driver circuit 240 and the driver 205 are implemented.

Since the supply voltage Vddl powering the output stage 208 is much lower than the core voltage, the voltage swing of the output signal is much lower than the core voltage (i.e., lower by at least Vt). The low output voltage swing can significantly reduce power consumption, and enable faster signal switching times for higher data rates, as discussed further below.

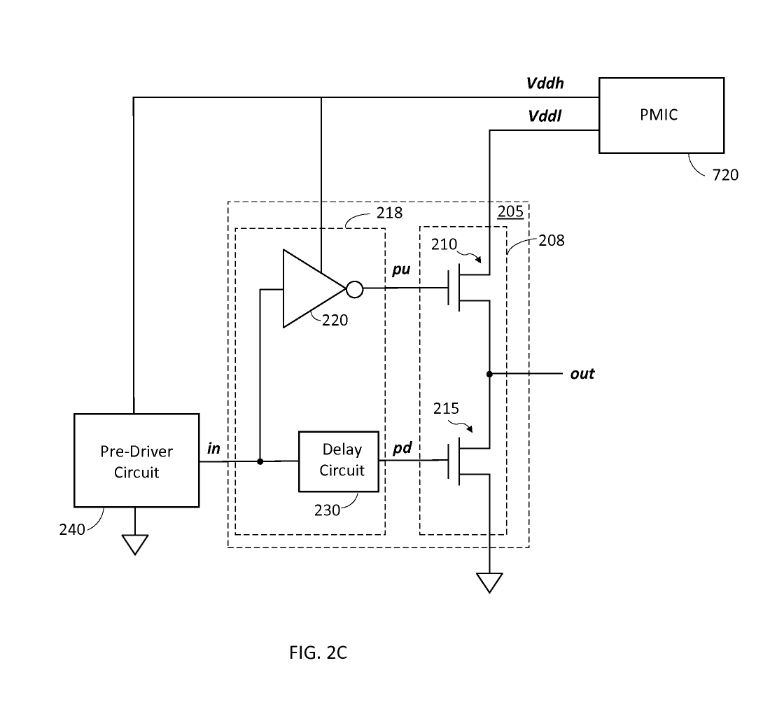

FIG. 3 shows an exemplary implementation of the inverter 220 according to an embodiment of the present disclosure. In this example, the inverter 220 comprises a PMOS transistor 310 and an NMOS transistor 320. The source of the PMOS transistor 310 is coupled to supply voltage Vddh, the gate of the PMOS transistor 310 is coupled to the input of the inverter 220, and the drain of the PMOS transistor 310 is coupled to the output of the inverter 220. The drain of the NMOS transistor 320 is coupled to the output of the inverter 220, the gate of the NMOS transistor 320 is coupled to the input of the inverter 220, and the source of the NMOS transistor 320 is coupled to ground.

In operation, the inverter 220 inverts the pull-down signal at the inverter input to generate the pull-up signal at the inverter output, which drives the gate of the pull-up NMOS transistor 210. More particularly, when the pull-down signal is high, the NMOS transistor 320 is turned on and the PMOS transistor 310 is turned off As a result, the NMOS transistor 320 pulls the gate of the pull-up NMOS transistor 210 low. In this case, the pull-up signal is low. When the pull-down signal is low, the NMOS transistor 320 is turned off and the PMOS transistor 310 is turned on. As a result, the PMOS transistor 310 pulls the gate of the pull-up NMOS transistor 210 up to approximately Vddh. In this case, the pull-up signal is high at a voltage of approximately Vddh. As discussed above, this fully turns on the pull-up NMOS transistor 210, even as the output voltage of the driver 205 approach supply voltage Vddl.

It is to be appreciated that the implementation of the inventor 220 shown in FIG. 3 is exemplary, and that the inventor 220 may be implemented using other circuits.

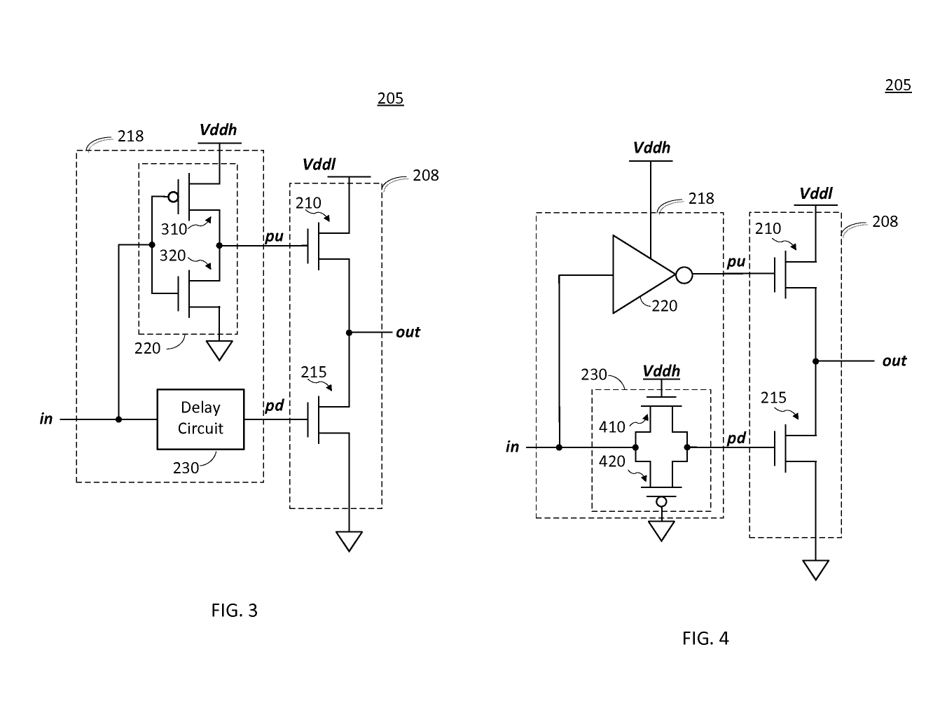

FIG. 4 shows an exemplary implementation of the delay circuit 230 according to an embodiment of the present disclosure. In this example, the delay circuit 230 comprises an NMOS transistor 410 and a PMOS transistor 420 coupled in parallel to form a complementary pass gate (also referred to as a transmission gate). The gate of the NMOS transistor 410 is coupled to supply voltage Vddh, and the gate of the PMOS transistor 420 is coupled to ground. As a result, the pass gate is turned on, allowing the pull-down signal to pass through the pass gate with a propagation delay. The propagation delay of the pass gate may be approximately matched to the delay of the inverter 220 so that the pull-up signal applied to the gate of the pull-up NMOS transistor 210 and the pull-down signal applied to the gate of the pull-down NMOS transistor 215 switch logic states at approximately the same time. In one example, the widths and/or lengths of the transistors 410 and 420 may be chosen so that the delay of the pass gate is approximately matched to the delay of the inventor 220. This matching delay may be critical to reduce variation in propagation delay between transmitting a pull-up transition versus a pull-down bit. Variation in propagation delay introduces duty cycle distortion of the outgoing data which is another form of deterministic jitter.

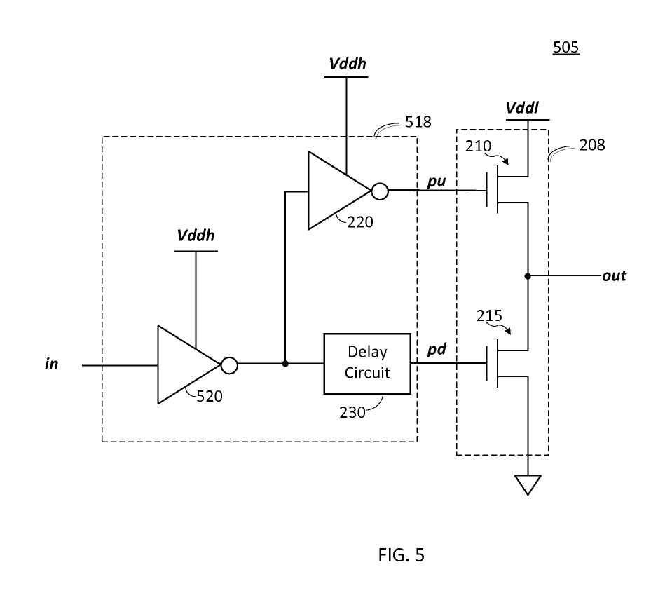

FIG. 5 shows an example of a driver 505 in which the drive circuit 518 further comprises a second inverter 520 coupled to the input of the first inverter 220 and the delay circuit 230. The second inverter 520 may be implemented using a complementary-pair inverter (an example of which is shown in FIG. 3) or other type of inverter. The second inverter 520 is powered by supply voltage Vddh, and therefore has an output voltage swing of approximately Vddh. The second inverter 520 receives an input signal from the pre-driver circuit 240 having a logic state that changes according to the data signal and/or clock signal being transmitted, and inverts the input signal to generate the pull-down signal with an output voltage swing of Vddh. In this example, the input signal to the second inverter 520 may have the same logic state as the pull-up signal.

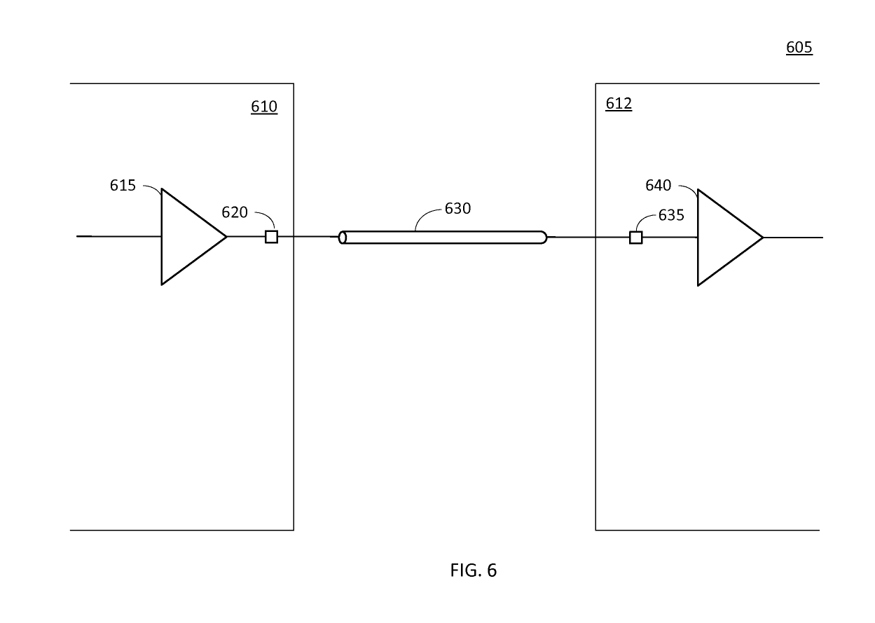

FIG. 6 shows a simplified example of a communication system 605 in which embodiments of the present disclosure may be used. The communication system 605 may be used to provide high-speed data communication (e.g., in the gigahertz range) between a device (e.g., memory controller) on a first chip 610 and a device (DDR SDRAM) on a second chip 612. To do this, the communication system 605 comprises a transmit driver 615 on the first chip 610 and a receiver 640 on the second chip 612. The transmit driver 615 may be implemented using the driver 205 shown in FIG. 2A, and may receive a data signal for transmission from the pre-driver circuit 240 shown in FIG. 2A. In operation, the transmit driver 615 transmits the data signal to the receiver 640 via a channel 630, as discussed further below.

In the example in FIG. 6, the first and second chips 610 and 612 may be mounted on a board (e.g., printed circuit board). In this example, the channel 630 may comprise a transmission line on the board. The communication system 605 may also comprise a first I/O pad 620 for coupling the transmit driver 615 to the channel 630, and a second I/O pad 635 for coupling the channel 630 to the receiver 640. It is to be appreciated that the communication system 605 may include additional structures (e.g., pins, bond wires, solder joints, etc.) coupling the transmit driver 615 and the receiver 640 to the channel 630.

To transmit data from the first chip 610 to the second chip 612, the transmit driver 615 transmits the corresponding data signal on the channel 630. The output voltage swing of the transmit driver 615 may be approximately equal to Vddl for the example in which the transmit driver 615 is implemented using the driver 205 in FIG. 2A. In certain aspects, the output voltage swing may be much lower than a core voltage of the first chip 610, which may be used to power the pre-driver circuit 240, the drive circuit 218, and other circuits (e.g., processing cores, memory controller, etc.) on the first chip 610. Thus, in these examples, the voltage swing of the signal transmitted across the channel 630 is much lower than the core voltage. This reduces power consumption at the transmit driver 615 and receiver 640, and enables faster signal switching times for higher data rates.

The receiver 640 receives the data signal from the channel 630, processes the received signal, and outputs the processed signal to other components on the second chip 612 for further processing. For the example in which the communication system 605 is used to provide communication between a memory controller and DDR SDRAM, the receiver 640 may compare the received signal with a reference voltage, and output a signal based on the comparison. For example, the receiver 640 may output a logic one when the received signal is above the reference voltage, and output a logic zero when the received signal is below the reference voltage.

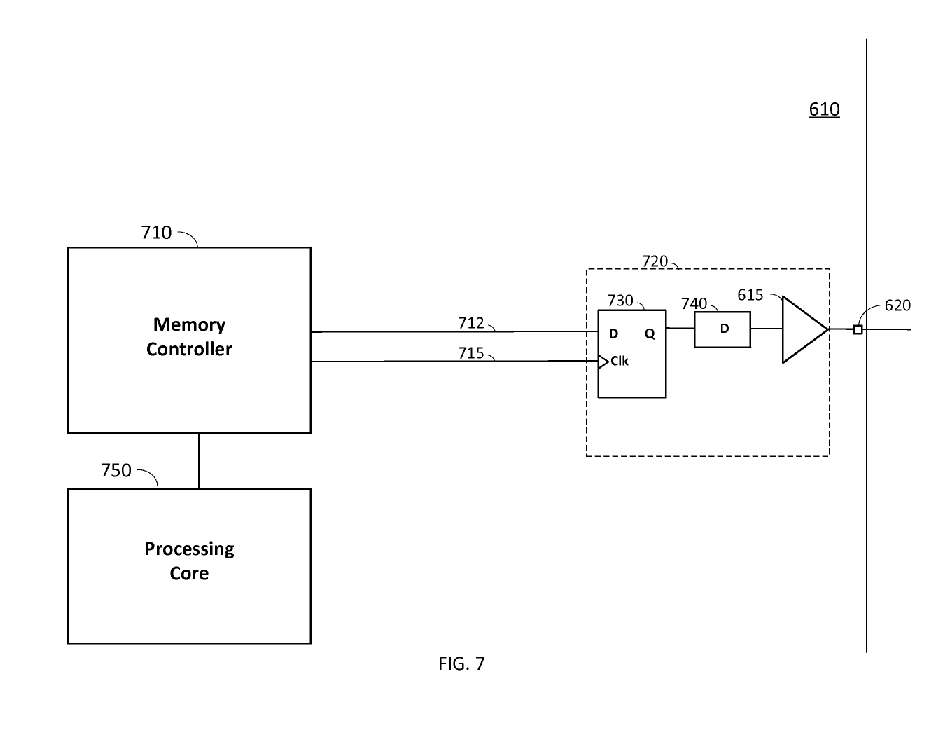

As discussed above, the communication system 605 in FIG. 6 may be used for communication between a memory controller and a memory device (e.g., DDR SDRAM). In this regard, FIG. 7 shows an example in which the transmit driver 615 is used to transmit a data signal from a memory controller 710 on the first chip 610 to a memory device on the second chip 612. The memory controller 710 is configured to manage the flow of data (e.g., read/write operations) between one or more circuits (e.g., processing core) on the first chip 610 and the external memory device on the second chip 612.

In this example, the first chip 610 comprises a physical (PHY) block 720 for sending a data signal from the memory controller 710 to the memory device on the second chip 612. Although one PHY block 720 is shown in FIG. 7 for simplicity, it is to be appreciated that the first chip 610 may comprise a plurality of PHY blocks for sending data signals to the memory device in parallel. In the example in FIG. 7, the PHY block 720 includes a latch 730, and a delay circuit 740. Also, in the example in FIG. 7, the first chip 610 comprises a processing core 750 coupled to the memory controller 710, in which the processing core 750 accesses the external memory device through the memory controller 710, as discussed further below. In this example, when the processing core 750 (e.g., CPU, GPU, etc.) has data that needs to written to the external memory device, the processing core 750 sends the data and a write request to the memory controller 710. In response to the write request, the memory controller 710 sends a data signal 712 comprising the data and a clock signal 715 to the PHY block 720. The clock signal 715 may be generated by a phase locked loop (PLL) and/or other clock source.

The latch 730 in the PHY block 720 receives the data signal 712 and the clock signal 715 from the memory controller 710. The latch 730 latches the data signal 712 using the clock signal 715. For example, the latch 730 may sample the data signal 712 on rising and/or falling edges of the clock signal 715 to synchronize the data signal 712 with the clock signal 715 at the PHY block 720. The delay circuit 740 may then delay the data signal by a desired amount. For example, the delay circuit 740 may delay the data signal to compensate for skew between different data lines between the first and second chips for the example in which multiple data signals are transmitted to the memory device in parallel using a plurality of PHY blocks. The transmit driver 615 then transmits the data signal across the channel 630 to the external memory device on the second chip 612. The transmit driver 615 may comprise any one of the drivers shown in FIGS. 2A-5. It is to be appreciated that the PHY block 720 may include additional circuits, and is not limited to the exemplary implementation shown in FIG. 7.

In certain aspects, each of the memory controller 710, processing core 750, latch 730 and delay circuit 740 may be powered by the core voltage of the first chip 610. In these aspects, the latch 730 and delay circuit 740 may be considered part of the pre-driver circuit 240 shown in FIG. 2A.

As discussed above, in certain aspects, the supply voltage Vddl powering the output stage 208 (i.e., voltage coupled to the drain of the pull-up NMOS transistor 210) is much lower than the core voltage of the corresponding chip, in which core voltage is used to power the pre-driver circuit 240, the drive circuit 218, and other circuits (e.g., processing core, memory controller, etc.) on the chip. For example, the supply voltage Vddl may be lower than the core voltage by at least the threshold voltage Vt of the pull-up NMOS transistor 210. This helps ensure that the gate-to-source voltage of the pull-up NMOS transistor 210 remains at or above the threshold voltage Vt, and therefore that the pull-up NMOS transistor 210 operates in the linear region. Operating the pull-up NMOS transistor 210 in the linear region causes the NMOS transistor 210 to have a low controllable impedance for preserving signal integrity, as discussed above. In contrast, operating the pull-up NMOS transistor 210 in the non-linear region (e.g., saturation) results in a highly non-linear impedance, which can lead to high non-linear signal distortion. In certain aspects, the low supply voltage Vddl may be lower than the core voltage by an amount exceeding the threshold voltage Vt to operate the pull-up NMOS transistor 210 deeper in the linear region. For example, the low supply voltage Vddl may be lower than the core voltage by an amount exceeding Vt by at least 20% of Vt.

In addition, making the low voltage supply Vddl much lower than the core voltage causes the output signal transmitted across the channel 630 to have a low voltage swing. This significantly reduces power consumption and increases signal switching times compared with a signal voltage swing at or close to the core voltage.

Further, making the low voltage supply Vddl much lower than the core voltage enables the pull-up signal (“pu”) to drive the pull-up NMOS transistor 210 into the linear region (i.e., Vg≧Vddl+Vt) without having to boost the core voltage. If the output stage 208 were powered by the core voltage (i.e., the drain of the pull-up NMOS transistor 210 were coupled to the core voltage instead of Vddl), then the voltage of the pull-up signal (“pu”) would need to be boosted above the core voltage to drive the pull-up NMOS transistor 210 into the linear region. A problem with this approach is that boosting the core voltage is typically done using a charge pump, which is noisy, and consumes a relatively large amount of power and chip area. By making Vddl lower than the core voltage instead of boosting the voltage of the pull-up signal (“pu”) above the core voltage, the drawbacks associated with using a charge pump are avoided.

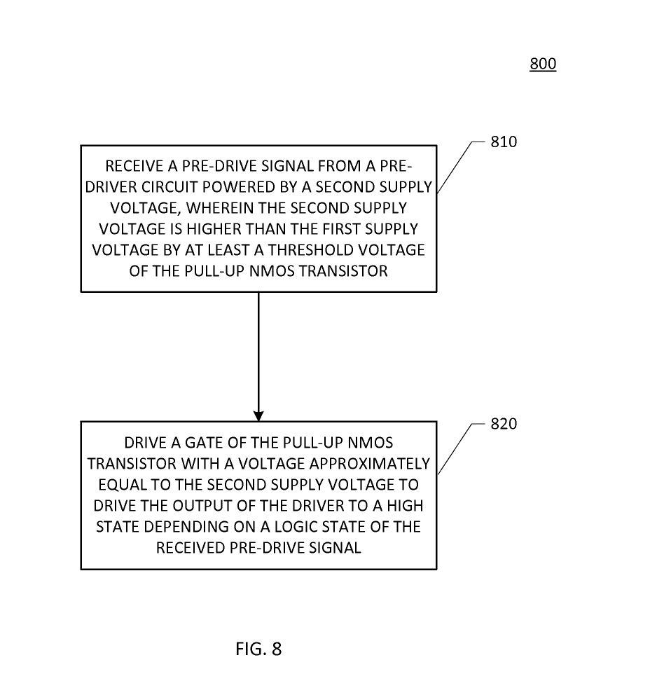

FIG. 8 is a flowchart illustrating a method 800 for driving a driver according to an embodiment of the present disclosure. The driver comprises a pull-up NMOS transistor (e.g., pull-up NMOS transistor 210) having a drain coupled to a first power supply (e.g., Vddl) and a source coupled to an output of the driver.

In step 810, a pre-drive signal is received from a pre-driver circuit powered by a second supply voltage, wherein the second supply voltage is higher than the first supply voltage by at least a threshold voltage of the pull-up NMOS transistor. For example, the second supply voltage may be a core voltage, in which case, the pre-driver circuit (e.g., pre-driver circuit 240) is powered by the core voltage. The core voltage may be used to power other circuits (e.g., processing core 750, memory controller 710, etc.) implemented on the same chip as the driver and pre-drive circuit. The pre-drive signal may be the output signal of the pre-drive circuit, and may comprise a data signal and/or clock signal to be transmitted by the driver (e.g., across a channel).

In step 820, a gate of the pull-up NMOS transistor is driven with a voltage approximately equal to the second supply voltage to drive the output of the driver to a high state depending on a logic state of the received pre-drive signal. For instance, for the example of the driver 205 in FIG. 2A, the gate of the pull-up NMOS transistor (e.g., pull-up NMOS transistor 210) may be driven high when the logic state of the pre-drive signal is low (e.g., output signal of the pre-driver circuit 240 is low). For the example of the driver 505 in FIG. 5, the gate of the pull-up NMOS transistor (e.g., pull-up NMOS transistor 210) may be driven high when the logic state of the pre-drive signal is high.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A system, comprising:
a pre-driver circuit powered by a first supply voltage, and configured to output a pre-drive signal; and
a driver, the driver comprising:
a pull-up NMOS transistor having a drain coupled to a second supply voltage, and a source coupled to an output of the driver, wherein the second supply voltage is lower than the first supply voltage by at least a threshold voltage of the pull-up NMOS transistor; and
a drive circuit coupled to a gate of the pull-up NMOS transistor, wherein the drive circuit is configured to receive the pre-drive signal and to drive the gate of the pull-up NMOS transistor with a voltage approximately equal to the first supply voltage to drive the output of the driver to a high state depending on a logic state of the pre-drive signal.

2. The system of claim 1, wherein the drive circuit comprises an inverter having an input coupled to the pre-driver circuit and an output coupled to the gate of the pull-up NMOS transistor, wherein the inverter is powered by the first supply voltage.

3. The system of claim 1, wherein the driver further comprises a pull-down NMOS transistor having a drain coupled to the output of the driver, and a source coupled to a ground, wherein the drive circuit is coupled to a gate of the pull-down NMOS transistor and is configured to drive the gate of the pull-down NMOS transistor with a voltage approximately equal to the first supply voltage to drive the output of the driver to a low state depending on the logic state of the pre-drive signal.

4. The system of claim 3, wherein the drive circuit comprises:
an inverter having an input coupled to the pre-driver circuit and an output coupled to the gate of the pull-up NMOS transistor, wherein the inverter is powered by the first supply voltage; and
a delay circuit having an input coupled to the pre-driver circuit and an output coupled to the gate of the pull-down NMOS transistor, wherein the delay circuit is powered by the first supply voltage.

5. The system of claim 4, wherein a delay of the delay circuit approximately equals a propagation delay of the inverter.

6. The system of claim 1, wherein the output of the driver has a voltage swing approximately equal to the second supply voltage.

7. The system of claim 6, wherein the pre-drive signal has a voltage swing approximately equal to the first supply voltage.

8. The system of claim 1, wherein the first supply voltage is a core voltage used to power a processing core on a chip on which the system is implemented.

9. The system of claim 1, wherein the pre-driver circuit comprises a latch configured to receive an input signal and a clock signal, to latch the input signal using the clock signal to generate an output signal, wherein the pre-drive signal is based on the output signal and the latch is powered by the first supply voltage.

10. The system of claim 1, wherein the system is implemented on a chip, and the first supply voltage and second supply voltage are provided by a power source external to the chip.

11. A method for driving a driver, the driver comprising a pull-up NMOS transistor having a drain coupled to a first power supply and a source coupled to an output of the driver, the method comprising:
receiving a pre-drive signal from a pre-driver circuit powered by a second supply voltage, wherein the second supply voltage is higher than the first supply voltage by at least a threshold voltage of the pull-up NMOS transistor; and
driving a gate of the pull-up NMOS transistor with a voltage approximately equal to the second supply voltage to drive the output of the driver to a high state depending on a logic state of the received pre-drive signal.

12. The method of claim 11, wherein the driver further comprises a pull-down NMOS transistor having a drain coupled to the output of the driver, and a source coupled to a ground, and wherein the method further comprises:
driving a gate of the pull-down NMOS transistor with a voltage approximately equal to the second supply voltage to drive the output of the driver to a low state depending on the logic state of the received pre-drive signal.

13. The method of claim 11, wherein the output of the driver has a voltage swing approximately equal to the first supply voltage.

14. The method of claim 13, wherein the pre-drive signal has a voltage swing approximately equal to the second supply voltage.

15. The method of claim 11, wherein the second supply voltage is a core voltage used to power a processing core on a chip on which the driver and pre-driver circuit are implemented.

16. An apparatus for driving a driver, the driver comprising a pull-up NMOS transistor having a drain coupled to a first power supply and a source coupled to an output of the driver, the apparatus comprising:
means for receiving a pre-drive signal from a pre-driver circuit powered by a second supply voltage, wherein the second supply voltage is higher than the first supply voltage by at least a threshold voltage of the pull-up NMOS transistor; and
means for driving a gate of the pull-up NMOS transistor with a voltage approximately equal to the second supply voltage to drive the output of the driver to a high state depending on a logic state of the received pre-drive signal.

17. The apparatus of claim 16, wherein the driver further comprises a pull-down NMOS transistor having a drain coupled to the output of the driver, and a source coupled to a ground, and wherein the apparatus further comprises:
means for driving a gate of the pull-down NMOS transistor with a voltage approximately equal to the second supply voltage to drive the output of the driver to a low state depending on the logic state of the received pre-drive signal.

18. The apparatus of claim 16, wherein the output of the driver has a voltage swing approximately equal to the first supply voltage.

19. The apparatus of claim 18, wherein the pre-drive signal has a voltage swing approximately equal to the second supply voltage.

20. The apparatus of claim 16, wherein the second supply voltage is a core voltage used to power a processing core on a chip on which the driver and pre-driver circuit are implemented.
